(19) United States
(12) Patent Application Publication
(10) Pub. No.: US 2007/0035938 A1
(43) Pub. Date: Feb. 15, 2007

(54) Printed circuit board assembly

(75) Inventors: Craig Rochford, Hampshire (GB); Sean Rochford, Hampshire (GB); Mark Andrew Woodiwiss, Cardiff (GB)

Correspondence Address: DYKEMA GOSSETT PLLC, FRANKLIN SQUARE, THIRD FLOOR WEST, 1300 I STREET, NW, WASHINGTON, DC, 20005, US

(73) Assignee: ARKA TECHNOLOGIES LIMITED, London (GB)

(21) Appl. No.: 10/564,196

(22) PCT Filed: Jul. 9, 2004
(86) PCT No.: PCT/GB04/02977

§ 371 Date: Jun. 20, 2006

(30) Foreign Application Priority Data
Jul. 11, 2003 (GB) 0316364.9

(51) Int. Cl. H05K 9/00

(52) U.S. Cl. 361/816; 361/759

(57) ABSTRACT

The present invention relates to printed circuit board (PCB) assemblies and particularly, but not exclusively, to a system for shielding components from radio frequency interference (RFI) and more particularly to a system for shielding surface mounted devices (SMD). The invention provides an assembly comprising a PCB (4) and a component (2) realisably mounted thereon by securing means. The securing means comprises a resiliently flexible and sprung bias clip member secured to one of the PCB (4) and said component (2); and first and second surfaces provided on the other of the PCB (4) and said component (2). The first surface is arranged to can and thereby resiliently flex said clip member in a first direction against the clip member bias, and the second surface is arranged so as to allow the said clip member to move, by means as said by us, in a second direction opposite to said first direction. The clip member maybe thereby latched on said second surface so as to provide resistance to the PCB and said component being disassembled.

The present invention relates to printed circuit board (PCB) assemblies and particularly, but not exclusively, to a system for shielding components from radio frequency interference (RFI) and more particularly to a system for shielding surface mounted devices (SMD).

It is well known in the design of electrical equipment to reduce the undesirable affects of RFI by shielding components mounted on a printed circuit board (PCB) with a shielding can manufactured from an electrically conductive material such as beryllium copper. This type of shielding can has hithertofore been traditionally mounted to a PCB with surface mounting techniques such as soldering. However, a problem associated with these techniques is that, once secured in position on a PCB, a shielding can cannot be readily removed. As a consequence, the replacement or repair of devices covered by the shield is considerably complicated. Any subsequent redesign of a PCB provided with a shielding can is also complicated and expensive.

It is an object of the present invention to provide a system for allowing a component to be releaseably mounted to a PCB. More particularly, it is an object of the present invention to provide a system for allowing a shielding can to be removeably mounted to a PCB.

A first aspect of the present invention provides a printed circuit board (PCB) assembly comprising a PCB and a component mounted thereon, wherein the PCB and component are releaseably secured to one another by securing means; characterised in that said securing means comprises a resiliently flexible and sprung biased clip member secured to one of the PCB and said component; and first and second surfaces provided on the other of the PCB and said component, said first surface being arranged to cam and thereby resiliently flex said clip member in a first direction against the bias of the clip member when the PCB and said component are initially pressed together during assembly, and said second surface being arranged so as to allow said clip member to move, by means of said bias, in a second direction opposite to said first direction when the PCB and said component are further pressed together, said clip member thereby latching on said second surface so as to provide resistance to the PCB and said component being disassembled.

The PCB and said component may be secured to one another so that the clip member is sprung biased into abutment with said second surface. Furthermore, said second surface may be disposed at such an angle relative to the clip member that the spring bias of the clip member biases the PCB and said component toward one another when the PCB and said component are in abutment with one another.

Ideally, the securing means comprises a further resiliently flexible and sprung biased clip member secured to one of the PCB and said component, the further clip member being located so that the spring bias of the two clip members acts generally in a direction opposite to each other. It is particularly desirable for the clip members to be located substantially opposite one another so that the spring bias of each clip member acts generally in the direction of the other clip member. Ideally, the or each clip member is secured to one of the PCB and said component by virtue of the or each clip member being cut from the material of said PCB or component.

Furthermore, the or each clip member may be secured to said component, and said first and second surfaces may be provided on the PCB. Said component is preferably a radio frequency interference shield. The first and second surfaces may be provided on a slug which is originally discrete from the PCB and said component.

A second aspect of the present invention provides a printed circuit board (PCB) assembly comprising a PCB and a component mounted thereon, wherein the PCB and component are releasably secured to one another by securing means; characterised in that said securing means comprises a resiliently flexible and sprung biased clip member secured to one of the PCB and said component; and at least one slug secured to the other of the PCB and said component and being originally descrete from the PCB and said component. The slug may have a cross-section taken perpendicular to the longitudinal axis of the slug which is quadrilateral, pentagonal, hexagonal, septagonal or octagonal in shape.

Embodiments of the present invention will now be described with reference to the accompanying drawings, in which:

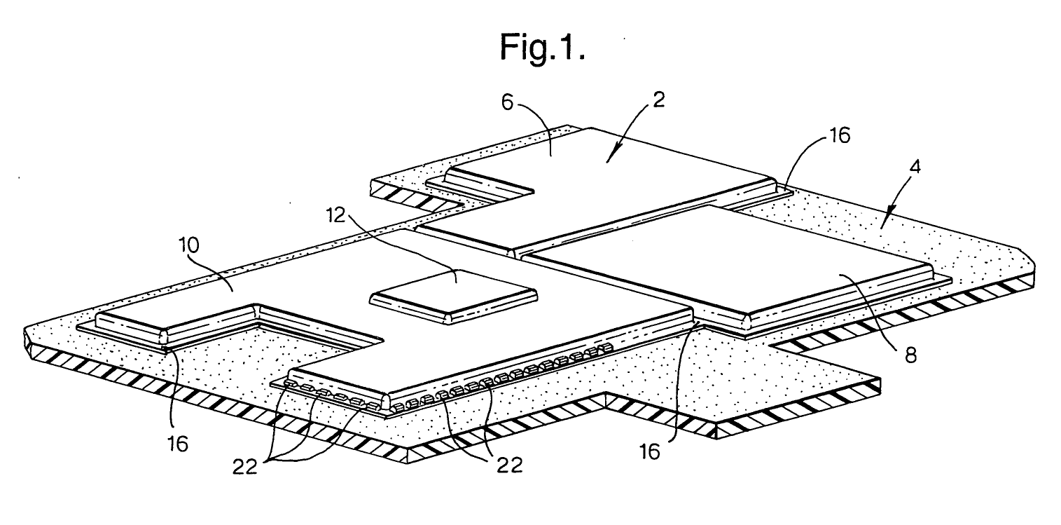

FIG. 1 is a perspective view of a multi-compartment shield can removeably secured to a printed circuit board (PCB) in accordance with the present invention;

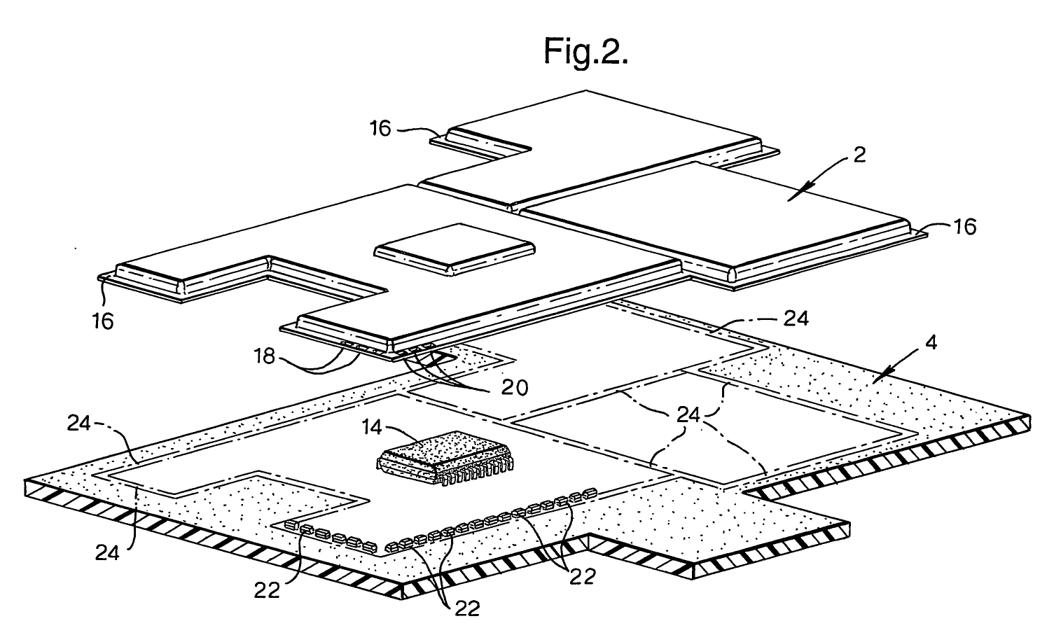

FIG. 2 is a perspective view of the shield can and PCB of FIG. 1 separate from one another;

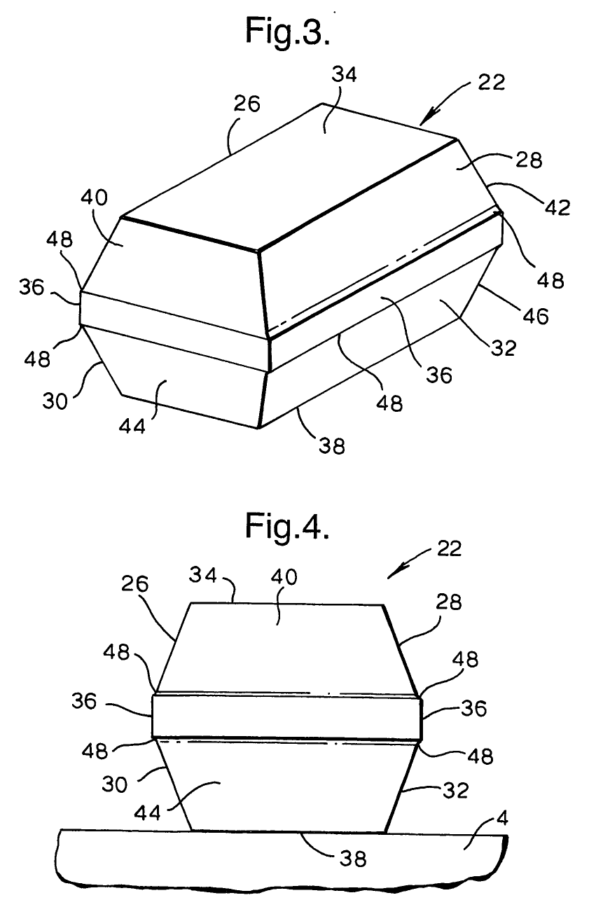

FIG. 3 is a perspective view of one of the slugs shown provided on the PCB of FIGS. 1 and 2;

FIG. 4 is an end view of the slug shown in FIG. 3;

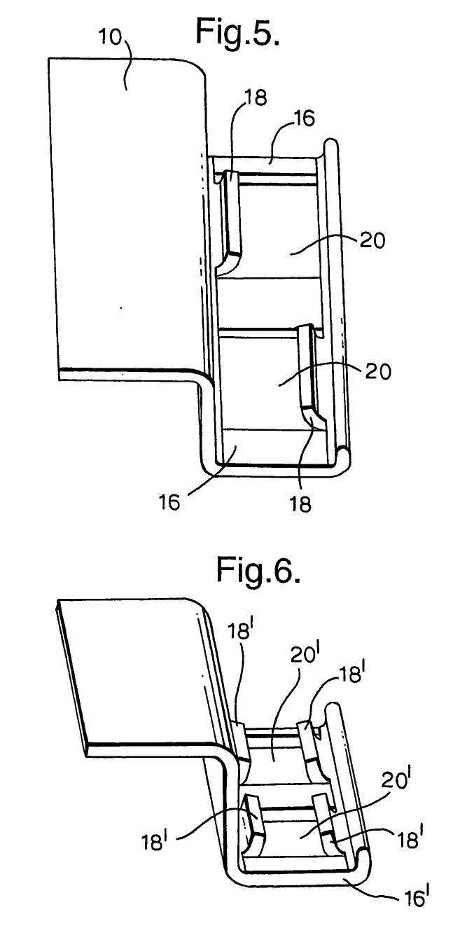

FIG. 5 is a perspective partial view of the can of FIGS. 1 and 2 wherein two clips for releaseably engaging two PCB slugs are illustrated;

FIG. 6 is a perspective partial view of a second can wherein two alternative clips for releaseably engaging two PCB slugs are illustrated;

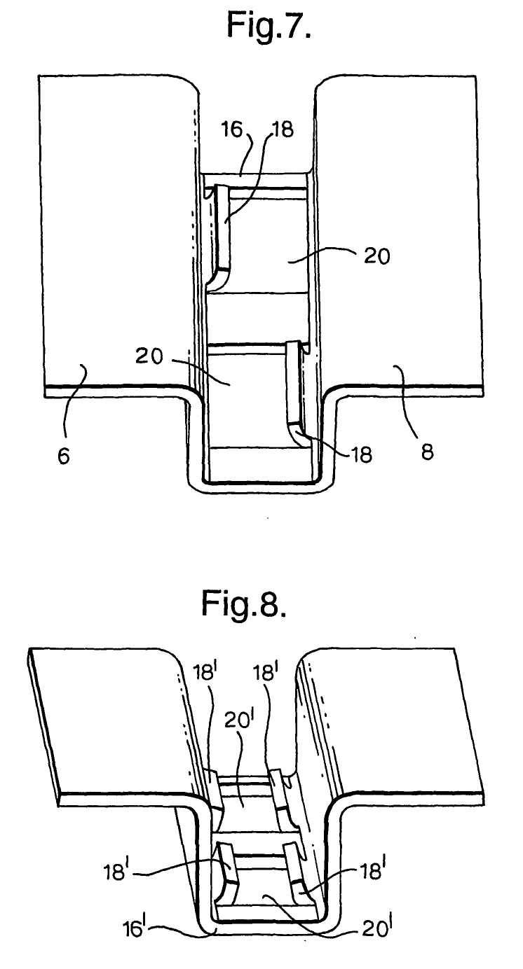

FIG. 7 is a perspective partial view of the can of FIGS. 1 and 2 wherein two clips for releaseably engaging two PCB slugs are illustrated;

FIG. 8 is a perspective partial view of the can of FIG. 6 wherein two alternative clips for releaseably engaging two PCB slugs are illustrated;

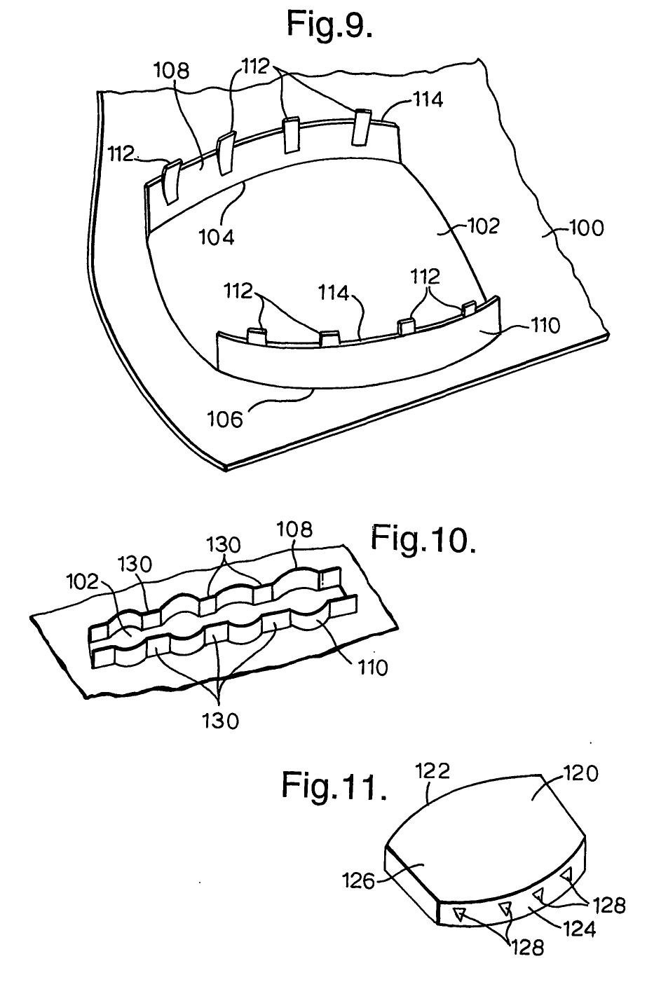

FIG. 9 is a perspective partial view of a further can wherein a further alternative clip for releaseably engaging a PCB slug is illustrated;

FIG. 10 is a perspective partial view of a yet further can wherein a plurality of further clips for releaseably engaging a plurality of PCB slugs is illustrated;

FIG. 11 is a perspective view of an alternative slug for releaseable engagement with the clips of FIGS. 9 and 10; and

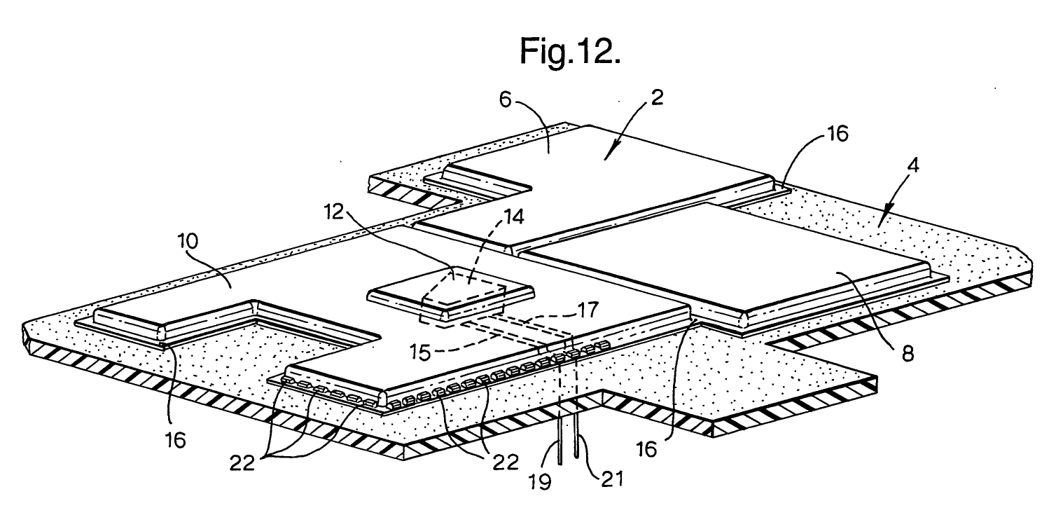

FIG. 12 is a perspective view of the shield can of FIG. 1 modified so as to receive a component on the underside thereof.

A radio frequency interference (RFI) shielding can 2 and printed circuit board (PCB) 4 arranged in accordance with the present invention is shown in FIG. 1 of the accompanying drawings. The multi-compartment can 2 is releaseably secured to the PCB 4. The shielding can 2 comprises three compartments 6, 8, 10 for isolating different areas of the PCB 4 from radio frequency interference. The third compartment 10 has a raised section 12 which assists in accommodating a device 14 surface mounted to the PCB 4 (see FIG. 2). The shielding can 2 has the same basic construction as a conventional shielding can, however the peripheral edge of each compartment 6, 8, 10 which contacts the PCB 4 is provided with a flange 16. The flange 16 extends outwardly from each compartment 6, 8, 10 and lies in a plane parallel with the portion of PCB 4 with which it is to engage. The flange 16 extends between the three compartments 6, 8, 10 and connects these compartments 6, 8, 10 together.

As will be most clearly seen from FIGS. 5 and 7 of the accompanying drawings, each can compartment 6, 8, 10 is surrounded by a plurality of clip members 18 mounted to the flange 16. Each clip member 18 is cut from the material of the flange 16 and bent upwardly about a hinge line delimiting the clip member 18 from the remainder of the shielding can 2. More specifically, in relation to each clip member 18, three of the four straight sides of a square aperture 20 in the flange 16 are cut into said flange 16 so as to provide a tab of material which may be subsequently bent about the fourth side of the square aperture 20 and thereby form the aforesaid clip member 18. The length of the clip member 18 may be trimmed as appropriate. Indeed, the profile of each clip member 18 may be trimmed so that the clip member has a shape and/or size different to that of the aperture 20.

The clip members 18 may be stamped from the flange 16, trimmed as necessary and bent about the hinge line in a single manufacturing process. It will be understood that the multi-compartment can 2 may be stamped from a single sheet of material in a single step using conventional production techniques.

With reference to FIGS. 5 and 7, it will be seen that neighbouring clip members 18 are located on opposite sides of the aperture 20. The view of FIG. 5 illustrates two adjacent clip members 18 provided on the portion of flange 16 extending about the perimeter of the multi-compartment can 2 as a whole. The view of FIG. 7 shows two neighbouring clip members 18 extending from a portion of flange 16 located between two can compartments 6, 8. In an alternative embodiment as shown in the partial views of FIGS. 6 and 8, it will be seen that two clip members 18′ extend upwardly from opposite sides of each square aperture 20′ in the flange 16′. This alternative embodiment therefore comprises twice as many clip members as the first embodiment and this has the effect of providing a stronger connection between the shielding can and the associated PCB. Further arrangements of the clip members 18 may be provided. For example, the clip members may have a triangular shape and extend upwardly from all four sides of an associated square flange aperture. The clip members may also be bent downwardly in an opposite direction to that shown in the accompanying drawings so as to project below the flange (ie so as to project from the side of the flange opposite to that from which the can compartments extend).

In order for the multi-compartment can 2 to be secured to the PCB 4 in a releaseable fashion by means of the clip members 18 (or indeed by means of the alternative clip members alluded to above), the PCB 4 is provided with a plurality of projections or slugs 22. The slugs 22 are positioned along tracks 24 which co-locate with the flange 16 when the PCB 4 and shield can 2 are assembled. For the sake of simplicity, only a small number of slugs 22 are shown in FIGS. 1 and 2 located along the tracks 24. However, in the preferred embodiment, the slugs 22 will be located along the full length of the tracks 24 so that the clip members 18 located along the entire perimeter of each shield can compartment 6, 8, 10 can latch onto the PCB 4.

The slugs 22 may be secured to the PCB 4 with any suitable surface mounting technique. For example, the slugs 22 may be secured with solder or adhesive. Each slug should be designed in such a way that the associated clip member is able to be resiliently latched about a surface of the slug. By way of example, it will be seen from FIGS. 3 and 4 of the accompanying drawings that each slug 22 (designed for engagement with the clip members 18, 18′ shown in FIGS. 5, 6, 7 and 8) is provided with upper sloping surfaces 26, 28 and lower sloping surfaces 30, 32. Each upper sloping surface 26, 28 is planar and slopes, at an angle of 15° to the vertical, from an upper horizontal planar surface 34 to a horizontally extending ridge 36. Furthermore, each lower sloping surface 30, 32 is planar and slopes outwardly, at an angle of 15° to the vertical, from a lower horizontal planar surface 38 to the horizontally extending ridge 36. The upper and lower horizontal planar surfaces 34, 38 are of the same size and rectangular shape and the upper surface 34 is located directly above the lower planar surface 38.

The upper sloping surfaces 26, 28 extend downwards from the long edges of the rectangular upper surface 34 and the lower sloping surfaces 30, 32 extend upwardly from the long edges of the lower rectangular surface 38. Further upper sloping surfaces 40, 42 also slope outwardly from the short edges of the upper rectangular surface 34 to the ridge 36. Similarly, further lower sloping surfaces 44, 46 slope outwardly from the short edges of the lower rectangular surface 38 to the ridge 36. The smaller upper and lower sloping surfaces 40, 42, 44, 46 may form the same angle with the vertical as the large upper and lower sloping surfaces 26, 28, 30, 32. However, said small sloping surfaces may have a different slope angle to that of the large sloping surfaces. It will also be appreciated that each of the large sloping surfaces 26, 28, 30, 32 may have differing sloping angles. It is envisaged however that the large sloping surfaces will have the same degree of slope and have an angle to the vertical of between 10° and 15°.

The ridge 36 provides a flat vertical surface extending around the slug 22 midway between the upper and lower horizontal planar surfaces 34, 38. The flat surface of the ridge 36 extends laterally (horizontally) beyond the large sloping surfaces 26, 28, 30, 32 and is connected to said large surfaces by means of a small radius (ie a part cylindrical surface) 48. The ridge 36 and radius 48 connecting to the lower sloping surfaces 30, 32 combine in use to provide a latch against which the clip members engage to retain the shielding can 2 in position.

During assembly, the shielding can 2 is offered up to the PCB 4 as shown in FIG. 2 so that the flange 16 aligns with the tracks 24. The slugs 22 have been previously positioned on the tracks 24 so as to then align with the apertures 20 in the flange 16. As the shield can 2 is pressed against the PCB 4, the slugs 22 pass through the apertures 20 and the clip 18 member associated with each aperture 20 abuts one of the upper sloping surfaces 26, 28 and, as the can 2 is further pressed towards the PCB 4, the clip member 18 is cammed outwardly by said upper sloping surface. In camming the clip member 18, the associated slug 20 resiliently bends the clip member. The materials from which shield cans are traditionally manufactured ensures that the clip member 18 is inherently resilient and has a tendency to spring back to its original position.

As the shield can 2 is continued to be pressed towards the PCB 4, the clip member 18 passes over the ridge 36. At this point, the clip 18 is deformed to its greatest extent during the assembly process and it is important that this level of deformation does not exceed the elastic limit of the clip member 18. In other words, having been deformed by an upper sloping surface of the slug 22, the clip member 18 must still be capable of moving back towards its original undeformed position as a consequence of its inherent resilience. Consequently, as the shield can 2 is yet further pressed towards its final position in abutment with the PCB 4, the clip member 18 locates below the ridge 36 against one of the lower sloping surfaces 30, 32 and/or one of the radii 48 adjoining said lower sloping surfaces. However, the geometry and size of the slug 22 relative to the clip member 18 is such that abutment of the flange 16 with the PCB 4 prevents the clip member 18 from locating back in its original undeformed position. Thus, due to its inherent resilience, the clip member 18 remains sprung biased towards its original position and thereby applies a force to the abutting lower sloping surface which biases the shield can 2 towards the PCB 4. This has the effect of preventing the PCB 4 and shield can 2 vibrating loosely against one another. The lower radius 48 adjoining the lower sloping surface abutting the clip member 18 also provides resistance to the can 2 being removed from the PCB 4. With all the clip members 18 securely located between the PCB 4 and the ridge 36 of each slug 22, the shield can 2 is securely and releaseably mounted to the PCB 4.

In order to release the shield can 2 from the PCB 4, the shield can 2 is pulled upwardly from the PCB 4 so that the clip members 18 are cammed outwardly by the lower sloping surfaces 30, 32. Once the clip members 18 pass over the respective ridges 36, the clip members 18 will press against the upper sloping surfaces 26, 28 and, due to their inherent resilience and spring bias, will tend to spring the can 2 from the PCB 4.

It will be apparent to the skilled reader that if the thickness of the shield can is increased then the depth of the slugs may also need to be increased so as to allow the clip members to locate between the PCB 4 and the slug ridge 36.

Further embodiments of the present invention are shown in FIGS. 9, 10 and 11 of the accompanying drawings. In FIG. 9, a partial view of a shield flange is illustrated with an alternative type of clip arrangement. The flange 100 is provided with an aperture 102 with opposing part circular edges 104, 106 from which part cylindrical walls 108, 110 are upstanding. The two walls 108, 110 each comprise four clip members 112 which extend upwardly from an upper wall edge 114. The clip members 112 are equi-spaced along each upper wall edge 114. The clip members 112 may be formed by shearing and thereby drawing material from the upstanding walls 108, 110. The clip members 112 may also be bent inwardly over the aperture 102 so as to more readily engage a slug located in the aperture 102.

A shield can provided with the clip arrangement shown in FIG. 9 may be used with a slug design similar to that shown in FIGS. 3 and 4 (although the large upper and lower sloping surfaces and the ridge of that particular slug design should be curved so as to ensure engagement with the clip members 112 which themselves are arranged on a part circular line). A slug 120 ideally suited for use with the clip arrangement of FIG. 9 is shown in FIG. 11. This slug 120 comprises opposing part cylindrical side walls 122, 124 and is generally of the same size and shape (in plan view) as the aperture 102. The arrangement of the slug 120 and aperture 102 is such that the upper horizontal planar surface 126 of the slug 120 may be pushed through the aperture 102 so that the side walls 122, 124 of the slug 120 abut the clip members 112. Four equi-spaced recesses 128 located in each side wall 122, 124 are positioned so as to receive the clip members 112 once the flange 100 has been pressed over the slug 120 and into abutment with a PCB to which the slug 120 is attached. The clip members 112 latch into the recesses 128 and thereby secure the flange 100 adjacent the PCB. The clip members 112 and/or the recesses 128 may be provided with a camming surface which allows the clip members 112 to lift from the recesses 128 when the flange 100 is pulled from the PCB. In this way, a shield can may be repeatedly secured to and removed from a PCB.

With reference to a yet further embodiment, FIG. 10 shows a clip arrangement wherein four of the clip arrangements of FIG. 9 are shown in a series with the apertures 102 thereof connected with further apertures in the flange so as to form one generally elongate flange aperture. Also, in the arrangement of FIG. 10, the side walls 110, 114 are connected by means of vertical planar walls 130 so as to provide a continuous wall along each side of the elongate flange aperture. Although not illustrated in FIG. 10, each part cylindrical side wall 108, 110 is provided with four equi-spaced clip members as in the arrangement of FIG. 9.

Suitable dimensions and materials for use in connection with the aforementioned PCB and shield can will be apparent to a reader skilled in the art. The slugs may be injection moulded, diecast or stamped, although other manufacturing processes may also be appropriate. The slugs may be of zinc or a polymer or be tin plated and may be positioned on a PCB using standard surface mount pick and place techniques. The slugs may also be manufactured in accordance with standard SMT sizes. For example, the slug may have a length of 40 thousandths of an inch (1.574 mm) and a maximum width of 20 thousandths of an inch (0.787 mm). Alternatively, in order to reduce the number of slugs used, the length of each slug may be increased (for example, to approximately 12 mm). The slugs may also have curved surfaces rather than the flat faceted surfaces shown in the accompanying embodiments. The slugs may, for example, be essentially spherical with a flattened portion which may be used for engagement with the PCB. It can also be desirable for the slugs to be symmetrical about one or more planes so that they may be secured to the PCB in two or more orientations without affecting their operation. This allows the slugs to be more readily located on the PCB by an automated process using standard pick-and-place techniques. It will be understood that the slugs shown in the accompanying drawings are symmetrical about a central plane and may be located on the PCB upside down without having their effectiveness degraded. A cross section of a slug taken perpendicularly to the longitudinal axis may have a quadrilateral, pentagonal, hexagonal, septagonal or octagonal shape. As such, a large number of slugs may be stored in a hopper and delivered to pick-and-place equipment without the risk of the slugs becoming entangled with one another. The clip members and apertures in the can flange should be sized appropriately with regard being had to the size of the slugs. The shielding can may be manufactured from beryllium copper and the underside of the can flange which contacts the PCB can be coated with an insulating material.

The connection of the shield can to the PCB by means of the present invention may be sufficiently strong for the shield can to be used as a structural component, for example, an equipment housing.

The invention is not limited to the particular embodiments described above. Alternative arrangements and suitable materials will be apparent to a reader skilled in the art. For example, as shown in FIG. 12, the device 14 may be mounted to the underside of the shielding can 2 rather than to the PCB 4 itself. Alternatively, devices may be mounted to both the underside of the shielding can 2 and the PCB 4. In this way, the number of electrical devices which may be supported by the PCB 4 (either directly or indirectly via the shielding can 2) may be significantly increased. It will be apparent to the skilled person that the depth of the shielding can 2 may need to be increased so as to allow for a double thickness of electrical devices located between the PCB 4 and the upper surface of the can 2.

In any of the previously described embodiments, the underside of the shielding can may be coated with an insulating material. In this way, the shielding can may be electrically insulated from all components with which it physically contacts (for example the PCB 4 and the slugs 22). However, when one or more devices are mounted to the underside of the can 2 it will be apparent that insulation will be required adjacent the underside surface of the can 2 in at least the local area where the device is positioned. Electrical conductive tracks similar to those conventionally found on a PCB may also be laid on the underside of the can 2 so as to provide electrical communication to devices mounted thereon. Again, it will be apparent to a skilled reader that these tracks may be laid on an insulating base material coated on the underside of the can 2. If necessary, a further insulating layer of material may be laid over the conducting tracks so that the tracks are effectively encapsulated in insulating material. This may be of particular use where a track extends between the flange 16 of the can 2 and the PCB 4. At such a location, a track may be electrically connected to a slug 22 so that the slug 22 itself becomes part of the electrical pathway associated with the track. Alternatively, the track may extend around the slugs 22 or a slug 22 may be omitted so as to provide sufficient room for passage of the track. A clip member 18 and aperture 20 associated with the omitted slug 22 may also be omitted so as to more readily facilitate passage of the track. Having passed (or at least extended to) the flange 16, the track may continue along a surface of the PCB 4 or may extend as a conventional conductive wire away from the PCB 4 and associated can 2. By way of example, the modified embodiment shown in FIG. 12 comprises a device 14 mounted to the underside of the raised section 12 of the shielding can 2 and has two electrically conductive tracks 15, 17 mounted on the underside of the can 2 and extending from the device 14 to a section of flange 16. Insulating material is sandwiched between the can 2 and the device 14 and associated tracks 15, 17. The tracks 15, 17 are electrically connected to two wires 19, 21 extending from the PCB at the flange 16.

1. A printed circuit board (PCB) assembly comprising a PCB and a component mounted thereon, wherein the PCB and component are releaseably secured to one another by securing means; characterised in that said securing means comprises a resiliently flexible and sprung biased clip member secured to one of the PCB and said component; and first and second surfaces provided on the other of the PCB and said component, said first surface being arranged to cam and thereby resiliently flex said clip member in a first direction against the bias of the clip member when the PCB and said component are initially pressed together during assembly, and said second surface being arranged so as to allow said clip member to move, by means of said bias, in a second direction opposite to said first direction when the PCB and said component are further pressed together, said clip member thereby latching on said second surface so as to provide resistance to the PCB and said component being disassembled.

2. An assembly as claimed in claim 1, wherein the PCB and said component are secured to one another so that the clip member is sprung biased into abutment with said second surface.

3. An assembly as claimed in claim 2, wherein said second surface is disposed at such an angle relative to the clip member that the spring bias of the clip member biases the PCB and said component toward one another when the PCB and said component are in abutment with one another.

4. An assembly as claimed in any of the preceding claims, wherein the securing means comprises a further resiliently flexible and sprung biased clip member secured to one of the PCB and said component, the further clip member being located so that the spring bias of the two clip members acts generally in a direction opposite to each other.

5. An assembly as claimed in claim 4, wherein said clip members are located substantially opposite one another so that the spring bias of each clip member acts generally in the direction of the other clip member.

6. An assembly as claimed in any of the preceding claims, wherein the or each clip member is secured to one of the PCB and said component by virtue of the or each clip member being cut from the material of said PCB or component.

7. An assembly as claimed in any of the preceding claims, wherein the or each clip member is secured to said component, and said first and second surfaces are provided on the PCB.

8. An assembly as claimed in any of the preceding claims, wherein said component is a radio frequency interference shield.

9. An assembly as claimed in any of the preceding claims, wherein the first and second surfaces are provided on a slug which is originally discrete from the PCB and said component.

10. A printed circuit board (PCB) assembly comprising a PCB and a component mounted thereon, wherein the PCB and component are releasably secured to one another by securing means; characterised in that said securing means comprises a resiliently flexible and sprung biased clip member secured to one of the PCB and said component; and at least one slug secured to the other of the PCB and said component and being originally descrete from the PCB and said component.

11. An assembly as claimed in claim 10, wherein the slug has a cross-section taken perpendicular to the longitudinal axis of the slug which is quadrilateral, pentagonal, hexagonal, septagonal or octagonal in shape.

12. An assembly as hereinbefore described with reference to, and as shown in, the accompanying drawings.
